(19) United States
(12) Patent Application Publication
(10) Pub. No.: US 2025/0351304 A1
(43) Pub. Date: Nov. 13, 2025

(54) EXTERNAL ELECTRONIC DEVICE

(71) Applicant: ASUSTEK COMPUTER INC., TAIPEI (TW)

(72) Inventors: Yu-Ning CHANG, TAIPEI (TW); Yu-Chi WANG, TAIPEI (TW); Yi-Ting CHEN, TAIPEI (TW); Po-Nien CHEN, TAIPEI (TW); Shin-Yu TUNG, TAIPEI (TW)

(21) Appl. No.: 18/772,651

(22) Filed: Jul. 15, 2024

(30) Foreign Application Priority Data
May 7, 2024 (TW) 113116858

(51) Int. Cl. H05K 7/20; G06F 1/20

(52) U.S. Cl. CPC H05K 7/2039; G06F 1/20

(57) ABSTRACT

A case for an electronic device is provided. The case includes an outer surface and an inner surface. The outer surface includes a plurality of first blind holes. The inner surface includes a plurality of second blind holes corresponding to the first blind holes. Each first blind hole and the corresponding second blind hole are three-dimensionally overlapped to form a through region extending through the case.

### CROSS-REFERENCE TO RELATED APPLICATION

This application claims the priority benefit of Taiwan Application Serial No. 113116858, filed on May 7, 2024. The entirety of the above-mentioned patent application is hereby incorporated by reference herein and made a part of specification.

### BACKGROUND OF THE INVENTION

### Field of the Invention

The disclosure relates to an electronic device, and in particular, to a case for an electronic device.

### Description of the Related Art

To meet a heat dissipation requirement, a straight-through hole is formed on a case of an electronic device (such as a notebook computer) as a heat dissipation hole, so that airflow flows through inside of the case to remove heat generated by operation of the electronic device.

Generally, to prevent dust from entering the inside of the case, a dimension of the heat dissipation hole should not be excessively large. However, a decrease in the dimension of the heat dissipation hole leads to a reduction in an opening ratio, and affects air intake efficiency and air venting efficiency of the case. Therefore, how to ensure a limitation of the dimension of the heat dissipation hole and a requirement of the opening ratio is a problem to be urgently resolved in the art.

### BRIEF SUMMARY OF THE INVENTION

The disclosure provides a case for an electronic device. The case includes an outer surface and an inner surface. The outer surface includes a plurality of first blind holes. The inner surface includes a plurality of second blind holes corresponding to the first blind holes. Each first blind hole and the corresponding second blind hole are three-dimensionally overlapped to form a through region extending through the case.

In the case for an electronic device of the disclosure, the first blind holes on the outer surface of the case and the second blind holes on the inner surface of the case are used to form the through region to replace a straight-through hole on a conventional case. The first blind holes and the second blind holes are three-dimensionally overlapped. A dimension of an opening on the case is determined by a dimension of a projection area (PA) of the through region along the thickness direction of the case. An opening ratio is determined by a dimension of a cross section perpendicular to an airflow direction at a position where the first blind hole and the second blind hole are three-dimensionally overlapped. In this way, the opening ratio of the case is increased without increasing a dimension of a heat dissipation hole, so as to ensure a limitation of the dimension of the heat dissipation hole and a requirement of the opening ratio.

### BRIEF DESCRIPTION OF THE DRAWINGS

FIG. 1 is a partial top view of a case for an electronic device according to a first embodiment of the disclosure.

FIG. 2 is a schematic cross-sectional view corresponding to a section line A-A in FIG. 1.

FIG. 3 is an enlarged view of a region B in FIG. 2.

FIG. 4 shows another embodiment of a blind hole structure according to the disclosure.

FIG. 5 is a partial top view of a case for an electronic device according to a second embodiment of the disclosure.

FIG. 6 is a partial top view of a case for an electronic device according to a third embodiment of the disclosure.

FIG. 7 is a partial top view of a case for an electronic device according to a fourth embodiment of the disclosure.

FIG. 8 is a partial top view of a case for an electronic device according to a fifth embodiment of the disclosure.

FIG. 9 is a partial top view of a case for an electronic device according to a sixth embodiment of the disclosure.

FIG. 10 is a partial top view of a case for an electronic device according to a seventh embodiment of the disclosure.

FIG. 11 is a partial top view of a case for an electronic device according to an eighth embodiment of the disclosure.

FIG. 12 is a partial top view of a case for an electronic device according to a ninth embodiment of the disclosure.

FIG. 13 is a partial top view of a case for an electronic device according to a tenth embodiment of the disclosure.

FIG. 14 is a partial top view of a case for an electronic device according to an eleventh embodiment of the disclosure.

FIG. 15 is a partial top view of a case for an electronic device according to a twelfth embodiment of the disclosure.

### DETAILED DESCRIPTION OF THE EMBODIMENTS

Specific embodiments of the disclosure are described in more detail below with reference to the schematic diagrams. Advantages and features of the disclosure are clearer based on the following descriptions and claims. It is to be noted that all the figures are in a very simple form and in an inaccurate proportion, and are merely intended to assist description of the purpose of the embodiments of the disclosure conveniently and clearly.

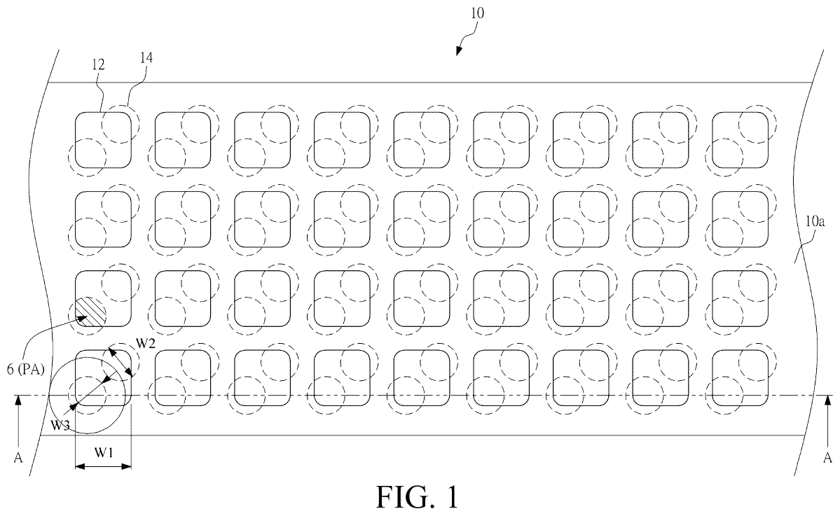

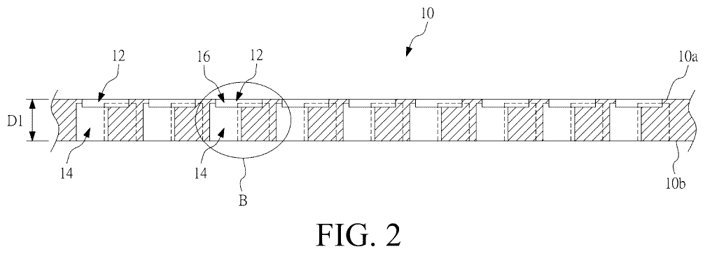

FIG. 1 is a partial top view of a case 10 for an electronic device according to a first embodiment of the disclosure. FIG. 2 is a schematic cross-sectional view corresponding to a section line A-A in FIG. 1. The case 10 is applicable to a notebook computer, a computer host, a server, or another electronic device that needs to use a heat dissipation hole to dissipate heat.

As shown in the FIG., the case 10 includes an outer surface 10a and an inner surface 10b. The outer surface 10a includes a plurality of first blind holes 12 arranged in an array. The inner surface 10b includes a plurality of second blind holes 14 corresponding to the first blind holes and arranged in an array. Each of the first blind holes 12 and the corresponding second blind hole 14 are three-dimensionally overlapped to form a through region 16 extending through the case 10.

The technical feature that the first blind hole 12 and the corresponding second blind hole 14 are three-dimensionally overlapped is described below.

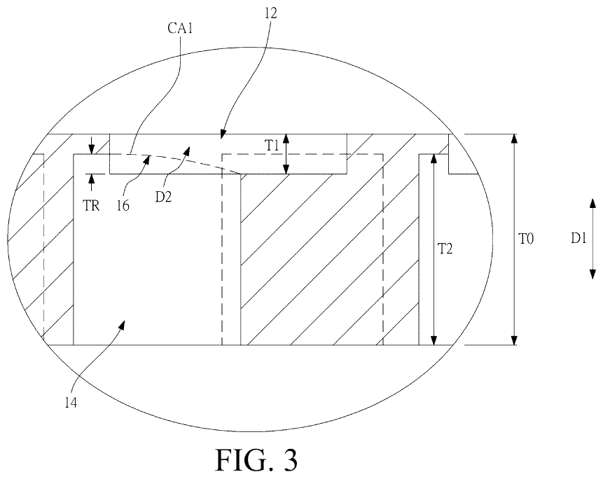

First, referring to FIG. 1 together, projection patterns of the first blind hole 12 and the second blind hole 14 (drawn by dashed lines in the FIG.) on the outer surface 10a of the case 10 partially overlap. In addition, referring to FIG. 3 together, FIG. 3 is an enlarged view of a region B in FIG. 2. The case 10 has a thickness direction D1. The case 10 has a thickness TO along the thickness direction D1. The first blind hole 12 has a first depth T1 along the thickness direction D1. The second blind hole 14 has a second depth T2 along the thickness direction D1. A sum of the first depth T1 and the second depth T2 is greater than the thickness TO, so that the first blind hole 12 and the second blind hole 14 are overlapped along the thickness direction D1.

The foregoing three-dimensional staggering means that the projection patterns of the first blind hole 12 and the corresponding second blind hole 14 on the outer surface 10a of the case 10 partially overlap, and the first blind hole 12 and the corresponding second blind hole 14 are overlapped along the thickness direction D1.

In an embodiment, considering structural strength of the case 10, when an opening area of the first blind hole 12 is greater than an opening area of the second blind hole 14, the first depth T1 is set to be less than the second depth T2.

In addition, referring to FIG. 1 together, the projection patterns of the first blind hole 12 and the second blind hole 14 (drawn by the dashed lines in the FIG.) on the outer surface 10a of the case 10 partially overlap. In other words, the first blind hole 12 and the corresponding second blind hole 14 are overlapped along a surface direction of the case 10. The foregoing three-dimensional staggering means that the first blind hole 12 and the corresponding second blind hole 14 are overlapped along the thickness direction D1, and the first blind hole 12 and the corresponding second blind hole 14 are overlapped along a surface of the case 10.

A corresponding dimension relationship among the first blind hole 12, the second blind hole 14, and the through region 16 is described below.

In this embodiment, an opening width w1 of the first blind hole 12 and an opening width w2 of the second blind hole 14 are greater than a preset width, and a width w3 of the through region 16 (perpendicular to the thickness direction D1) is less than the preset width. In this embodiment, the width w3 of the through region 16 refers to a smallest one of distances between any two opposite points on an edge of a projection area (PA) of the through region 16 in a projection direction that is the thickness direction D1 of the case 10.

The foregoing preset width is set based on a safety regulation (such as EN 62368-1). Specifically, when the first blind hole 12 and the second blind hole 14 are round holes, each of the opening width w1 of the first blind hole and the opening width w2 of the second blind hole refers to a diameter of the round hole. When the first blind hole 12 and the second blind hole 14 are square holes, each of the opening width w1 of the first blind hole and the opening width w2 of the second blind hole refers to a distance between two opposite sides of the square hole. In an embodiment, the foregoing preset width is set to be less than or equal to 1 mm to conform to standards of the safety regulation.

Next, in this embodiment, the first blind hole 12 and the corresponding second blind hole 14 include an overlapped depth TR along the thickness direction D1. The overlapped depth TR ensures that a through hole is formed between the first blind hole 12 and the second blind hole 14, and help ensure that the first blind hole 12 and the second blind hole 14 are three-dimensionally overlapped to provide a sufficient opening ratio.

Specifically, as shown in FIG. 3, a dimension of a flow channel through which gas flows through the through region 16 is determined by a cross section CA1 perpendicular to an airflow direction D2 in the figure. The airflow direction D2 is associated with the overlapped depth TR of the first blind hole 12 and the second blind hole 14. A dimension of the cross section CA1 is greater than a dimension of the PA of the through region 16 in the projection direction that is the thickness direction D1 of the case 10. In an embodiment, when an included angle between the airflow direction D2 and the thickness direction D1 is 30 degrees, a width of the cross section CA1 is approximately 1.15 times a width of the PA.

In this way, the overlapped depth TR of the first blind hole 12 and the second blind hole 14 and an overlapping ratio of projected areas of the first blind hole 12 and the second blind hole 14 on the outer surface 10a of the case 10 are properly adjusted, so that an area of the cross section CA1 of the flow channel of the through region 16 is greater than or equal to a pore diameter of a smaller one of the first blind hole 12 and the second blind hole 14, so as to increase an overall opening ratio of the case 10.

In a first embodiment shown in FIG. 3, bottom surfaces of the first blind hole 12 and the second blind hole 14 are both flat surfaces, but the disclosure is not limited thereto.

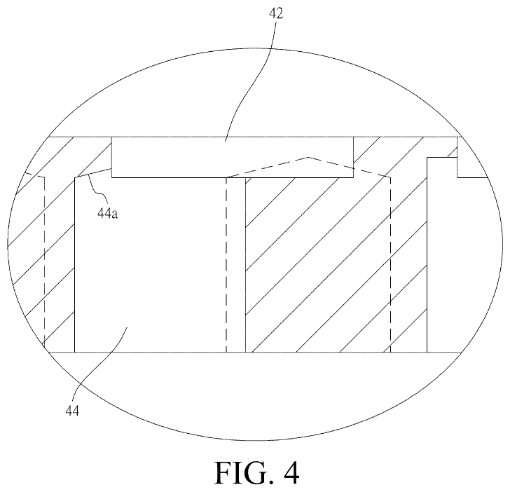

As shown in FIG. 4, FIG. 4 shows another embodiment of a blind hole structure according to the disclosure. In an embodiment, at least one of the first blind hole 42 and the second blind hole 44 includes a tapered bottom surface 44a, to help increase an opening ratio. In an embodiment of FIG. 4, the first blind hole 42 is a square hole with a flat bottom surface. The second blind hole 44 is a round hole, and a bottom of the round hole is the tapered bottom surface 44a.

Referring to FIG. 1 again, in the first embodiment of the case of the disclosure, an opening shape of the first blind hole 12 is different from an opening shape of the second blind hole 14. The first blind hole 12 is a square hole, and the second blind hole 14 is a round hole. The opening width w1 of the first blind hole 12 is greater than the opening width w2 of the second blind hole 14, but the disclosure is not limited thereto. In another embodiment, the first blind hole 12 and the second blind hole 14 also have a same opening shape. In an embodiment, both the first blind hole and the second blind hole are round holes or square holes. In still another embodiment, the opening width w1 of the first blind hole 12 is also the same as the opening width w2 of the second blind hole 14, or less than the opening width w2 of the second blind hole 14.

In addition, as shown in the FIG., in this embodiment, the first blind hole 12 includes two corresponding second blind holes 14. The two second blind holes 14 are arranged at positions symmetrical to each other, and in an embodiment, located at diagonal positions of the first blind hole 14, but the disclosure is not limited thereto. In another embodiment, each first blind hole 12 includes one, three, or more corresponding second blind holes 14.

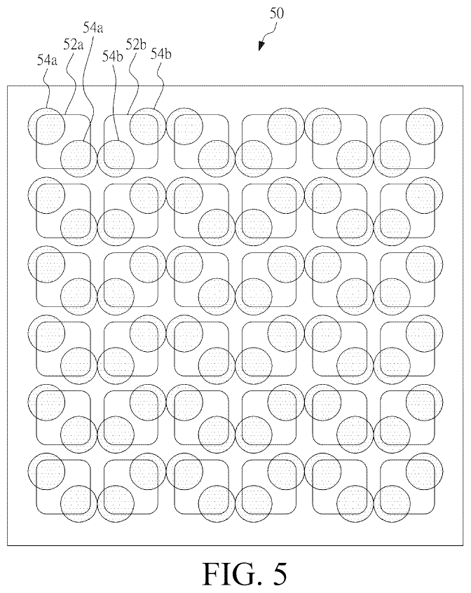

FIG. 5 is a partial top view of a case 50 for an electronic device according to a second embodiment of the disclosure.

Referring to FIG. 1 together, similar to the first embodiment of the case for an electronic device of the disclosure, in this embodiment, first blind holes 52a and 52b are square holes, and second blind holes 54a and 54b are round holes. Each of the first blind holes 52a and 52b includes two corresponding second blind holes 54a and 54b. The two second blind holes 54a and 54b are arranged at positions corresponding to diagonal positions of the first blind holes 52a and 52b.

However, different from the embodiment in FIG. 1, the second blind holes 14 corresponding to all of the first blind holes 12 are all located at upper right and lower left corners of the first blind holes 12. In this embodiment, the second blind holes 54a corresponding to the first blind holes 52a in an odd-numbered row have a different arrangement direction from the second blind holes 54b corresponding to the first bind holes 52b in an even-numbered row. As shown in the FIG., the second blind holes 54a corresponding to the first blind holes 52a in the odd-numbered row are located at upper left corner and lower right corners of the first blind hole 52a. The second blind holes 54b corresponding to the first blind holes 52b in the even-numbered row are located at upper and lower left corners of the first blind holes 52b.

In the foregoing embodiment, the arrangement positions of the second blind holes 54a and 54b are changed by distinguishing between the odd-numbered row and the even-numbered row, but the disclosure is not limited thereto. In another embodiment, the arrangement positions of the second blind holes 54a and 54b are also changed by distinguishing between an odd-numbered column and an even-numbered column.

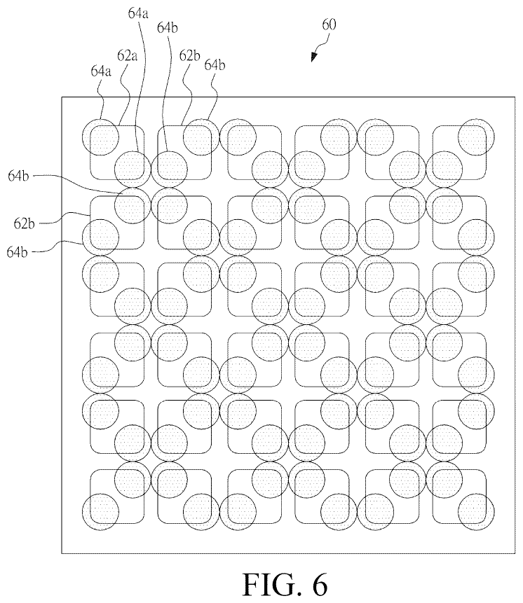

FIG. 6 is a partial top view of a case 60 for an electronic device according to a third embodiment of the disclosure.

Referring to FIG. 1 together, similar to the first embodiment of the case for an electronic device of the disclosure, in this embodiment, first blind holes 62a and 62b are square holes, and second blind holes 64a and 64b are round holes. Each of the first blind holes 62a and 62b includes two corresponding second blind holes 64a and 64b. The two second blind holes 64a and 64b are arranged at positions corresponding to diagonal positions of the first blind holes 62a and 62b.

However, different from the embodiment in FIG. 1, the second blind holes 14 corresponding to all of the first blind holes 12 are all located at upper right and lower left corners of the first blind holes 12. In this embodiment, the second blind holes 64a and 64b corresponding to the first blind holes 62a and 62b that are adjacent are arranged in different directions. The first blind hole 62a at an upper left corner is used as an example. The second blind holes 64a corresponding to the first blind hole are located at upper left and lower right corners of the first blind hole 62a. The second blind hole 64b corresponding to the first blind hole 62b located on a right side of the first blind hole 62a or below the first blind hole is located at upper right and lower left corners of the first blind hole 62b.

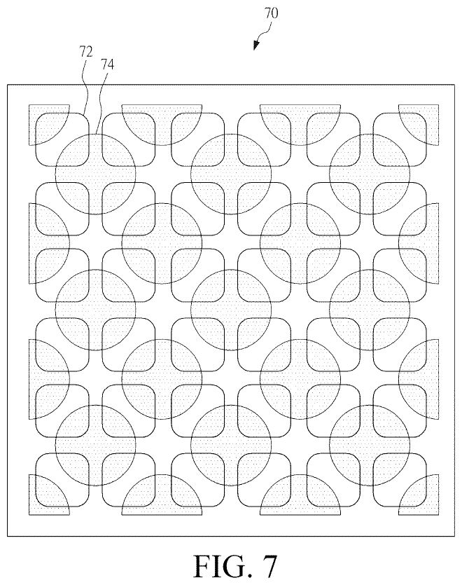

FIG. 7 is a partial top view of a case 70 for an electronic device according to a third embodiment of the disclosure.

Referring to FIG. 1 together, similar to the first embodiment of the case for an electronic device in the disclosure, in this embodiment, a first blind hole 72 is a square hole, and a second blind hole 74 is a round hole. However, in this embodiment, the second blind hole 74 is a large-sized round hole, and each second blind hole 74 is simultaneously three-dimensionally overlapped with four adjacent first blind holes 72.

In addition, it is to be noted that limited by an opening range at an edge position of the case 70, a semi-circular or 90-degree fan-shaped blind hole is formed to replace the original second blind hole 74, so as to make full use of space on the case 70.

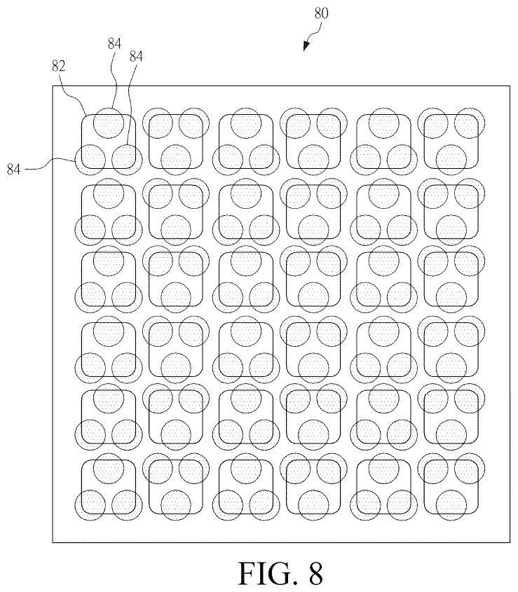

FIG. 8 is a partial top view of a case 80 for an electronic device according to a fourth embodiment of the disclosure.

Referring to FIG. 1 together, similar to the first embodiment of the case for an electronic device in the disclosure, in this embodiment, a first blind hole 82 is a square hole, and a second blind hole 84 is a round hole. However, different from the embodiment in FIG. 1, each first blind hole 12 includes two corresponding second blind holes 14 that are arranged at diagonal positions of the first blind hole 12. In this embodiment, the first blind hole 82 includes three corresponding second blind holes 84, and the three second blind holes 84 are symmetrically arranged around the first blind hole 82.

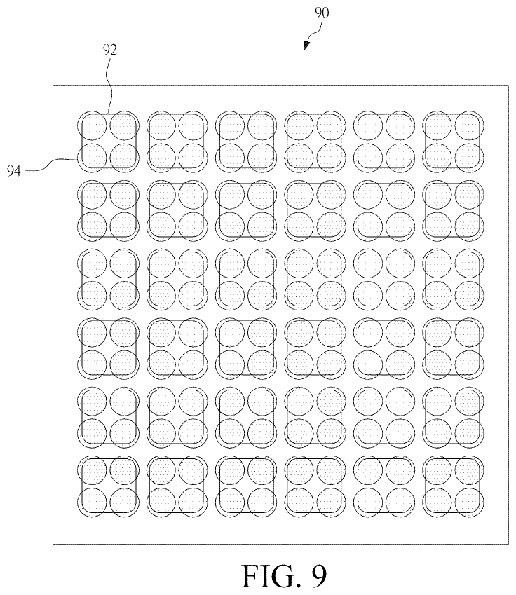

FIG. 9 is a partial top view of a case 90 for an electronic device according to a fifth embodiment of the disclosure.

Referring to FIG. 1 together, similar to the first embodiment of the case for an electronic device in the disclosure, in this embodiment, a first blind hole 92 is a square hole, and a second blind hole 94 is a round hole.

However, different from the embodiment in FIG. 1, each first blind hole 12 includes two corresponding second blind holes 14 that are arranged at diagonal positions of the first blind hole 12. In this embodiment, the first blind hole 92 includes four corresponding second blind holes 94, and the four second blind holes 94 are symmetrically arranged around the first blind hole 92.

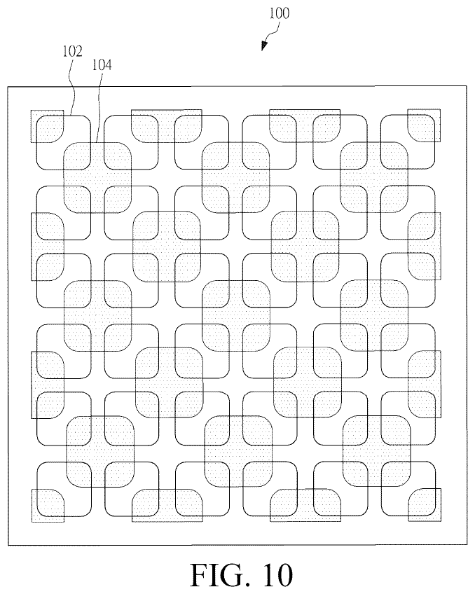

FIG. 10 is a partial top view of a case 100 for an electronic device according to a sixth embodiment of the disclosure.

Referring to FIG. 1 together, compared with the first embodiment of the case for an electronic device in the disclosure, in this embodiment, a first blind hole 102 and a second blind hole 104 are both square holes. Each first blind hole 102 includes two corresponding second blind holes 104. Arrangement positions of the two second blind holes 104 correspond to diagonal positions of the first blind hole 102. Each second blind hole 104 is a large-sized square hole (an opening area of the second blind hole 104 is greater than an opening area of the first blind hole 102), and is three-dimensionally overlapped with four adjacent first blind holes 102 simultaneously.

In addition, it is to be noted that limited by an opening range at an edge position of the case 100, the second blind hole 104 is divided into half or a quarter to replace the original complete second blind hole 104, so as to make full use of space on the case 100.

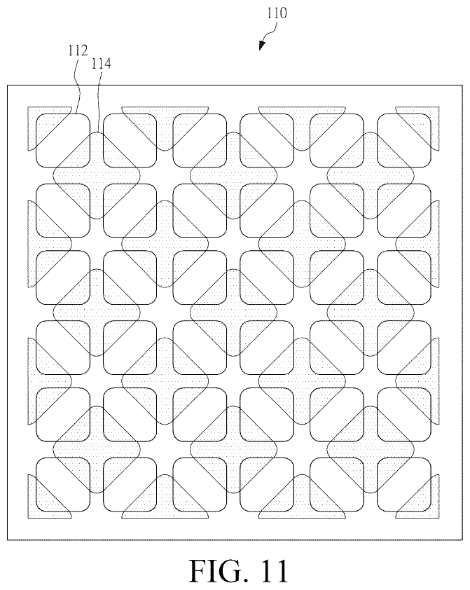

FIG. 11 is a partial top view of a case 110 for an electronic device according to a seventh embodiment of the disclosure.

Referring to FIG. 10 together, similar to the sixth embodiment of the case for an electronic device in the disclosure, in this embodiment, the first blind hole 112 and the second blind hole 114 are both square holes. Each first blind hole 112 includes two corresponding second blind holes 114. Arrangement positions of the two second blind holes 114 correspond to diagonal positions of the first blind hole 112. Each second blind hole 114 is a large-sized square hole (an opening area of the second blind hole 114 is greater than an opening area of the first blind hole 112), and is three-dimensionally overlapped with four adjacent first blind holes 112 simultaneously.

In addition, it is to be noted that limited by an opening range at an edge position of the case 110, the second blind hole 114 is divided into half or a quarter to replace the original complete second blind hole 114, so as to make full use of space on the case 110.

However, different from the embodiment in FIG. 10, a side of an opening of the first blind hole 102 and a side of an opening of the second blind hole 104 are parallel to each other. In this embodiment, the side of the opening of the second blind hole 112 has a 45-degree angle difference from the side of the opening of the first blind hole 114. To be specific, a diagonal direction of the opening of the second blind hole 114 is parallel to a side direction of the opening of the first blind hole 112.

In terms of an array formed by the first blind hole 112 and an array formed by the second blind hole 114, it is also understood that an angle difference of 45 degrees exists between the array formed by the first blind hole 112 and the array formed by the second blind hole 114.

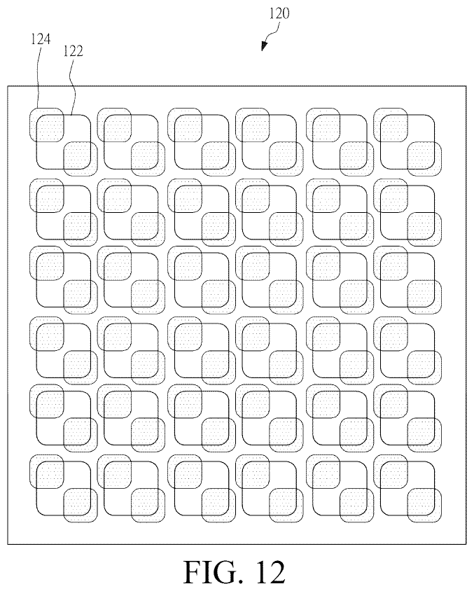

FIG. 12 is a partial top view of a case 120 for an electronic device according to an eighth embodiment of the disclosure.

Referring to FIG. 1 together, in this embodiment, a configuration of the first blind hole 122 and the second blind hole 124 is similar to that in the first embodiment of the disclosure. To be specific, the first blind hole 122 includes two corresponding second blind holes 124, and arrangement positions of the two second blind holes 124 correspond to diagonal positions of the first blind hole 122. However, in this embodiment, the first blind hole 122 and the second blind hole 124 are both square holes, instead of the second blind hole 14 being a round hole as shown in FIG. 1.

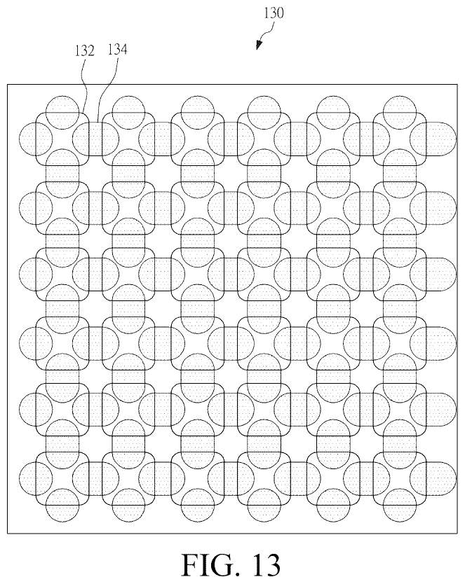

FIG. 13 is a partial top view of a case 130 for an electronic device according to a ninth embodiment of the disclosure.

Referring to FIG. 1 together, different from the first embodiment of the case for an electronic device in the disclosure, in this embodiment, a second blind hole 134 is a capsule hole.

In this embodiment, except for a first blind hole 132 located at an edge, each first blind hole 132 corresponds to and is three-dimensionally overlapped with four capsule holes (namely, the second blind hole 134), and a long side direction of each capsule hole is parallel to a side direction of the corresponding first blind hole 132.

In addition, it is to be noted that limited by an opening range at an edge position of the case 130, a round hole 136 is used to replace the original capsule hole, so as to make full use of space on the case 110.

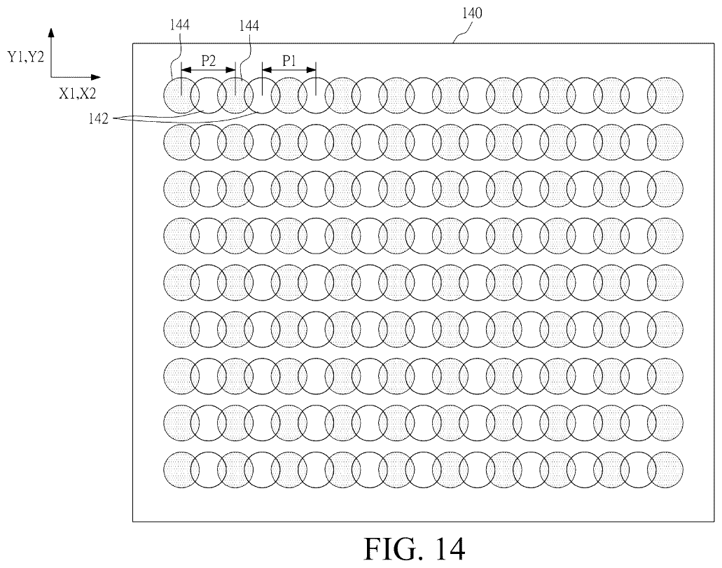

FIG. 14 is a partial top view of a case 140 for an electronic device according to a tenth embodiment of the disclosure.

In this embodiment, first blind holes 142 of the case 140 are spaced apart by a first distance P1, and arranged in an array on an outer surface of the case 140 along a first direction X1 and a second direction Y1. Second blind holes 144 are spaced apart by a second distance P2, and arranged in an array on an inner surface of the case 140 along a third direction X2 and a fourth direction Y2. The foregoing first distance P1 is the same as the second distance P2, the first direction X1 is perpendicular to the second direction X2, and the third direction Y1 is perpendicular to the fourth direction Y2. An array formed by the first blind holes 142 substantially corresponds to an array formed by the second blind holes 144, but a translation distance exists between the two arrays, so that the first blind hole 142 partially overlaps the corresponding second blind hole 144.

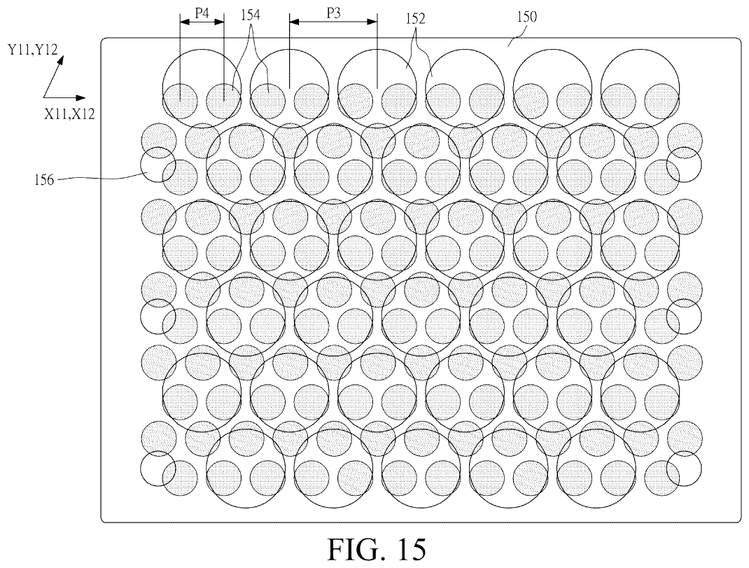

FIG. 15 is a partial top view of a case 150 for an electronic device according to an eleventh embodiment of the disclosure.

Referring to FIG. 14 together, compared with the tenth embodiment of the case for an electronic device in the disclosure, first blind holes 152 of the case 150 of this embodiment are spaced apart by a first distance P3, and arranged in an array on an outer surface of the case 150 along a first direction X11 and a second direction Y11. Second blind holes 154 are spaced apart by a second distance P4, and arranged in an array on an inner surface of the case 150 along a third direction X21 and a fourth direction Y21.

Different from the tenth embodiment of the disclosure, the first direction X1 is perpendicular to the second direction X2, and the third direction Y1 is perpendicular to the fourth direction Y2. In this embodiment, an included angle between the first direction X11 and the second direction Y11 is 60 degrees, and an included angle between the third direction X21 and the fourth direction Y21 is 60 degrees. In addition, different from the tenth embodiment of the disclosure, a dimension of the first blind hole 142 is the same as that of the second blind hole 144, and the first distance P1 is the same as the second distance P2. In this embodiment, a dimension of the first blind hole 152 is different from that of the second blind hole, and the first distance P3 is different from the second distance P4.

As shown in the FIG., in this embodiment, the dimension of the first blind hole 152 is greater than that of the second blind hole 154, and the first distance P3 is greater than the second distance P4. Limited by an opening range at an edge position of the case, a round hole 156 with a relatively small dimension is used to replace the original first blind hole 152, so as to make full use of space on the case.

In addition, a main feature of the disclosure is that a first blind hole 12 and a second blind hole 14 are three-dimensionally overlapped to form a through region 16. A layout of the first blind holes 12, 42, 52a, 52b, 62a, 62b, 72, 82, 92, 102, 112, 122, 132, 142, and 152 and the second blind holes 14, 44, 54a, 54b, 64a, 64b, 74, 84, 94, 104, 114, 124, 134, 144, and 154 is adjusted according to actual needs. In an embodiment, according to the actual needs, the layout of the first blind holes 12, 42, 52a, 52b, 62a, 62b, 72, 82, 92, 102, 112, 122, 132, 142, and 152 and the second blind holes 14, 44, 54a, 54b, 64a, 64b, 74, 84, 94, 104, 114, 124, 134, 144, and 154 described in the foregoing embodiment is also interchangeable.

In the case 10 for an electronic device of the disclosure, the first blind holes 12 on the outer surface 10a of the case 10 and the second blind holes 14 on the inner surface 10b of the case 10 are used to form the through region 16 to replace a straight-through hole on a conventional case. Since the first blind hole 12 and the second blind hole 14 are three-dimensionally overlapped, a dimension of an opening on the case 10 is determined by a dimension of a PA of the through region 16 along the thickness direction D1. An opening ratio is determined by a dimension of a cross section CA1 (the dimension of the cross-section CA1 is greater than the dimension of the PA) perpendicular to an airflow direction D2 at a position where the first blind hole 12 and the second blind hole 14 are three-dimensionally overlapped. In this way, the opening ratio of the case is increased without increasing a dimension of a heat dissipation hole, so as to ensure a limitation of the dimension of the heat dissipation hole and a requirement of the opening ratio.

The above is merely preferred embodiments of the disclosure, and do not impose any limitation on the disclosure. Any form of change such as an equivalent replacement or modification made by any person skilled in the art to technical means and technical content provided in the disclosure without departing from scope of the technical means of the disclosure is content that does not deviate from the technical means of the disclosure, and still falls within the protection scope of the disclosure.

What is claimed is:

1. A case for an electronic device, comprising an outer surface and an inner surface, wherein the outer surface comprises a plurality of first blind holes, the inner surface comprises a plurality of second blind holes corresponding to the first blind holes, and each of the first blind holes and the corresponding second blind hole are three-dimensionally overlapped to form a through region extending through the case.

2. The case for an electronic device according to claim 1, wherein the first blind holes are arranged in an array on the outer surface, and the second blind holes are arranged in an array on the inner surface.

3. The case for an electronic device according to claim 1, wherein an opening dimension of each of the first blind hole and the second blind hole is greater than a preset dimension, and an overlapping dimension of the through region is less than the preset dimension.

4. The case for an electronic device according to claim 1, wherein a shape of the first blind hole is different from that of the second blind hole.

5. The case for an electronic device according to claim 1, wherein an opening dimension of the first blind hole is greater than that of the second blind hole.

6. The case for an electronic device according to claim 5, wherein the first blind hole comprises a first depth, the second blind hole comprises a second depth, and the first depth is less than the second depth.

7. The case for an electronic device according to claim 5, wherein each of the first blind hole corresponds to more than two of the plurality of second blind holes symmetrically arranged around the first blind hole.

8. The case for an electronic device according to claim 1, wherein the case comprises a thickness along a thickness direction, the first blind hole comprises a first depth along the thickness direction, the second blind hole comprises a second depth along the thickness direction, and a sum of the first depth and the second depth is greater than the thickness.

9. The case for an electronic device according to claim 1, wherein the case comprises a thickness direction, the first blind hole and the corresponding second blind hole are overlapped along the thickness direction, and projection patterns of the first blind hole and the corresponding second blind hole on the outer surface are partially overlapped.

10. The case for an electronic device according to claim 9, wherein the first blind hole and the corresponding second blind hole has an overlapped depth along the thickness direction.

11. The case for an electronic device according to claim 1, wherein the second blind hole comprises a tapered bottom surface.
